(19) United States
(12) Patent Application Publication
(10) Pub. No.: US 2020/0052116 A1
(43) Pub. Date: Feb. 13, 2020

(54) SEMICONDUCTOR DEVICE

(71) Applicant: Samsung Electronics Co., Ltd., Suwon-si (KR)

(72) Inventors: SEUNG KWON KIM, Hwaseong-Si (KR); Yuri Masuoka, Seongnam-Si (KR)

(21) Appl. No.: 16/508,774

(22) Filed: Jul. 11, 2019

(30) Foreign Application Priority Data
Aug. 13, 2018 (KR) 10-2018-0094209

(51) Int. Cl. H01L 29/78; H01L 27/092; H01L 29/08; H01L 29/165; H01L 29/36; H01L 29/10; H01L 29/16

(52) U.S. Cl. CPC H01L 29/7848; H01L 27/0924; H01L 29/0847; H01L 29/1608; H01L 29/36; H01L 29/1037; H01L 27/0922; H01L 29/165

(57) ABSTRACT

A semiconductor device is provided. The semiconductor device includes a substrate including first through third regions, a first transistor of a first conductivity type disposed on the first region of the substrate and including a first channel layer, in which the first channel layer includes a first material, a second transistor of a second conductivity type different from the first conductivity type disposed on the second region of the substrate and including a second channel layer, in which the second channel layer includes the first material, and a third transistor of the second conductivity type disposed on the third region of the substrate and including a third channel layer, in which the third channel layer includes a second material different from the first material.

### CROSS-REFERENCE TO RELATED APPLICATION

This application claims priority under 35 U.S.C. § 119 to Korean Patent Application No. 10-2018-0094209, filed on Aug. 13, 2018, in the Korean Intellectual Property Office, the disclosure of which is incorporated by reference herein in its entirety.

### TECHNICAL FIELD

The present inventive concept relates to a semiconductor device.

### DISCUSSION OF RELATED ART

As semiconductor device continues to be highly integrated to have high performance and high reliability, the semiconductor device is generally required to be further miniaturized.

To miniaturize the semiconductor device, a technique for integrating a plurality of electronic elements (e.g., transistors) in a single semiconductor device is required. Therefore, the semiconductor device may include one or more P-type metal-oxide-semiconductor (PMOS) transistors formed in PMOS regions, and one or more N-type metal-oxide-semiconductor (NMOS) transistors formed in NMOS regions.

Two or more transistors having the same conductivity type may be classified into high performance transistors and general transistors. For example, a PMOS transistor may be classified as a high-performance PMOS transistor or a general PMOS transistor. A high-performance transistor generally refers to a transistor in which a driving current at the time of turning-on is greater than that of a general transistor.

To enhance the performance of the semiconductor device during the miniaturization process, a technique for forming both the high-performance transistor and the general transistor in a single semiconductor device is required.

### SUMMARY

Aspects of the present inventive concept provide a semiconductor device with enhanced product performance.

According to an exemplary embodiment of the present inventive concept, a semiconductor device includes a substrate including first through third regions, a first transistor of a first conductivity type disposed on the first region of the substrate and including a first channel layer, in which the first channel layer includes a first material, a second transistor of a second conductivity type different from the first conductivity type disposed on the second region of the substrate and including a second channel layer, in which the second channel layer includes the first material, and a third transistor of the second conductivity type disposed on the third region of the substrate and including a third channel layer, in which the third channel layer includes a second material different from the first material.

According to an exemplary embodiment of the present inventive concept, a semiconductor device includes a first source of a first conductivity type, a first drain of the first conductivity type spaced apart from the first source, a first channel layer disposed between the first source and the first drain and including a first material, a first gate structure disposed on the first channel layer, a second source of a second conductivity type different from the first conductivity type, a second drain of the second conductivity type spaced apart from the second source, a second channel layer disposed between the second source and the second drain and including a second material different from the first material, a second gate structure disposed on the second channel layer, a third source of the second conductivity type, a third drain of the second conductivity type spaced apart from the third source, a third channel layer disposed between the third source and the third drain and including a third material different from the first and second materials, and a third gate structure disposed on the third channel layer.

According to an exemplary embodiment of the present inventive concept, a semiconductor device includes a substrate including first and second regions, a first transistor of a first conductivity type disposed on the first region of the substrate and including a first channel layer including a first material, and a second transistor of the first conductivity type disposed on the second region of the substrate and including a second channel layer including a second material different from the first material, in which the first transistor includes: a first source/drain disposed on each of both sides of the first channel layer and including a third material having a first concentration, and a first buffer layer disposed between the first channel layer and the first source/drain and including the third material having a second concentration smaller than the first concentration.

Aspects of the present inventive concept are not restricted to the one set forth herein. The above and other aspects of the present inventive concept will become more apparent to one of ordinary skill in the art to which the present inventive concept pertains by referencing the detailed description of the present inventive concept given below.

### BRIEF DESCRIPTION OF THE DRAWINGS

Exemplary embodiments of the present inventive concept will be more clearly understood from the following detailed description taken in conjunction with the accompanying drawings, in which:

FIG. 1 is a cross-sectional view illustrating a semiconductor device according to an exemplary embodiment of the present inventive concept;

FIG. 2 is a cross-sectional view illustrating a semiconductor device according to an exemplary embodiment of the present inventive concept;

FIG. 3 is an enlarged cross-sectional view of “A” region of FIG. 2 for illustrating a first impurity region and a second impurity region according to an exemplary embodiment of the present inventive concept;

FIG. 4 is a cross-sectional view illustrating a semiconductor device according to an exemplary embodiment of the present inventive concept;

FIG. 5 is a cross-sectional view illustrating a semiconductor device according to an exemplary embodiment of the present inventive concept;

FIG. 6 is a cross-sectional view illustrating a semiconductor device according to an exemplary embodiment of the present inventive concept;

FIG. 7 is a cross-sectional view for explaining a semiconductor device according to an exemplary embodiment of the present inventive concept;

FIG. 8 is a cross-sectional view illustrating a semiconductor device according to an exemplary embodiment of the present inventive concept;

FIG. 9 is a layout diagram for explaining a semiconductor device according to an exemplary embodiment of the present inventive concept;

FIG. 10 is a cross-sectional view taken along line I-I′ of FIG. 9;

FIGS. 11 to 17 are intermediate step cross-sectional views for explaining a method of fabricating a semiconductor device according to an exemplary embodiment of the present inventive concept; and

FIGS. 18 to 20 are intermediate step cross-sectional views for explaining a method of fabricating a semiconductor device according to an exemplary embodiment of the present inventive concept.

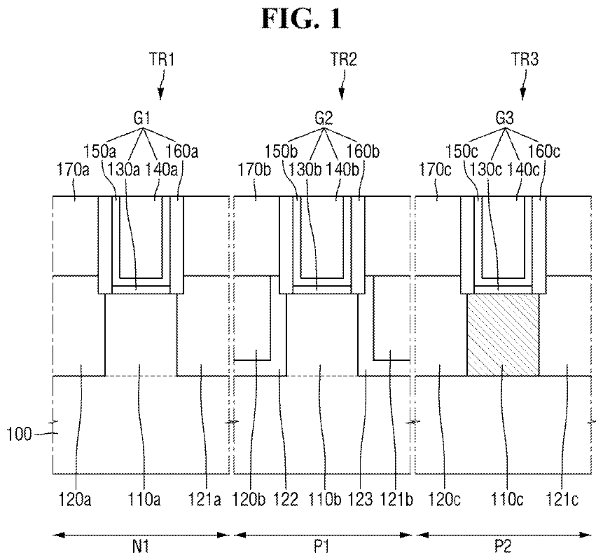

Since the drawings in FIGS. 1-20 are intended for illustrative purposes, the elements in the drawings are not necessarily drawn to scale. For example, some of the elements may be enlarged or exaggerated for clarity purpose.

### DETAILED DESCRIPTION OF THE EMBODIMENTS

In the accompany drawings of a semiconductor device according to an exemplary embodiment of the present inventive concept, a fin-type transistor including a channel region having a fin-type pattern shape is exemplarily illustrated, but the present inventive concept is not limited thereto. For example, the semiconductor device according to an exemplary embodiment of the present inventive concept may, of course, include, for example, a tunneling transistor (tunneling field effect transistor (FET)), a transistor including a nanowire, a transistor including a nanosheet or a three-dimensional (3D) transistor. In addition, the semiconductor device according to an exemplary embodiment of the present inventive concept may include, for example, a bipolar junction transistor (BJT), a lateral double diffused metal-oxide-semiconductor transistor (LDMOS) or the like. Although the semiconductor device according to an exemplary embodiment of the present inventive concept will be described as being a multi-channel transistor using a fin-type pattern, it is needless to say that the semiconductor device may be a planar transistor.

FIG. 1 is a cross-sectional view illustrating a semiconductor device according to an exemplary embodiment of the present inventive concept.

Referring to FIG. 1, the semiconductor device according to an exemplary embodiment of the present inventive concept may include a first transistor TR1, a second transistor TR2, and a third transistor TR3. Each of the first transistor TR1, the second transistor TR2, and the third transistor TR3 may be a fin-type transistor, but the present inventive concept is not limited thereto.

A substrate 100 may include a first N-type metal-oxide-semiconductor (NMOS) region N1, a first P-type metal-oxide-semiconductor (PMOS) region P1, and a second PMOS region P2. The first NMOS region N1, the first PMOS region P1, and the second PMOS region P2 may be regions separated from each other or may be regions connected to each other.

The substrate 100 may be, for example, bulk silicon (Si) or silicon-on-insulator (SOI). Alternatively, the substrate 100 may be a silicon substrate and/or may include other materials, for example, silicon germanium (SiGe), indium antimonide (InSb), lead tellurium (PbTe) compounds, indium arsenide (InAs), indium phosphide (InP), gallium arsenide (GaAs) or gallium antimonide (GaSb). Or, the substrate 100 may have an epitaxial layer formed on a base substrate.

According to an exemplary embodiment of the present inventive concept, the first transistor TR1 may be disposed on the first NMOS region N1 of the substrate 100. In addition, the second transistor TR2 may be disposed on the first PMOS region P1 of the substrate 100. Further, the third transistor TR3 may be disposed on the second PMOS region P2 of the substrate 100.

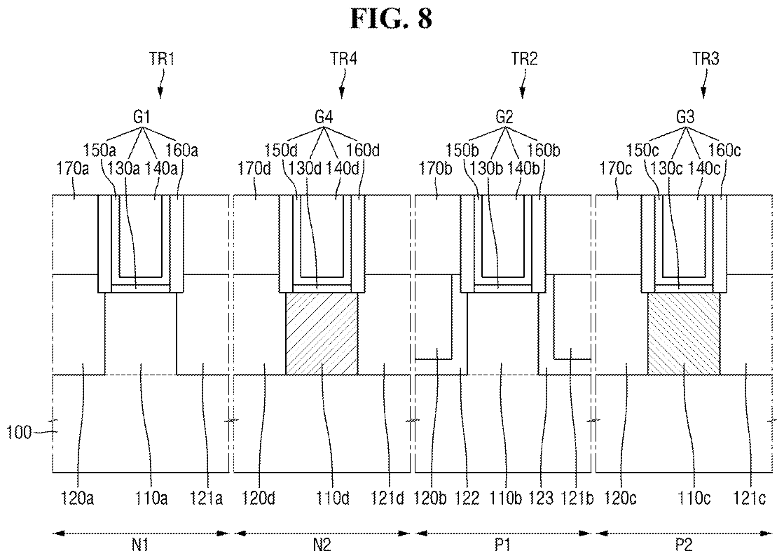

According to an exemplary embodiment of the present inventive concept, an NMOS transistor may be formed on the NMOS region (N1, N2 of FIG. 8) of the substrate 100. Further, a PMOS transistor may be formed on the PMOS region (P1, P2) of the substrate 100. In other words, the first transistor TR1 according to an exemplary embodiment of the present inventive concept may be an NMOS transistor, and the second transistor TR2 and the third transistor TR3 may be PMOS transistors. Since the NMOS transistor is made up of N-type source and drain and a P-type substrate, while the PMOS transistor is made up of P-type source and drain and a N-type substrate, the conductivity type of NMOS transistor may be N-type and the conductivity type of PMOS transistor may be P-type. Accordingly, the first transistor TR1 may have an N-type conductivity, while the second transistor TR2 and the third transistor TR3 may have a P-type conductivity different from the N-type conductivity.

In an exemplary embodiment of the present inventive concept, the driving current when the third transistor TR3 is turned on may be greater than the driving current when the second transistor TR2 is turned on. Thus, the third transistor TR3 may have a performance higher than that of the second transistor TR2. In an exemplary embodiment of the present inventive concept, the leakage current of the third transistor TR3 may be greater than the leakage current of the second transistor TR2.

The first transistor TR1 according to an exemplary embodiment of the present inventive concept may include a first channel layer 110a, a first source 120a, a first drain 121a, a first gate structure G1 and a first interlayer insulating film 170a.

The first channel layer 110a may be disposed on the first NMOS region N1 of the substrate 100, and may have a shape protruding from the first NMOS region N1 of the substrate 100. The first channel layer 110a may be a path through which carriers move from the first source 120a to the first drain 121a. For example, the first transistor TR1 formed on the first NMOS region N1 of the substrate 100 may be an NMOS transistor, and the carriers moving from the first source 120a to the first drain 121a may be electrons.

The first channel layer 110a may include a first material. For example, the first material may be silicon (Si), but the present inventive concept is not limited thereto.

Although an angle formed between the first channel layer 110a and the first NMOS region N1 of the substrate 100 is illustrated as a right angle in some of the drawings, the present inventive concept is not limited thereto. For example, the first channel layer 110a may have a tapered shape and/or may have a chamfered rectangular shape. Those having ordinary skill in the technical field of the present inventive concept may form the first channel layer 110a in various ways.

The first source 120a and the first drain 121a may be disposed on the first NMOS region N1 of the substrate 100. Further, the first source 120a and the first drain 121a may be disposed on both sides of the first channel layer 110a.

The first source 120a and the first drain 121a may be elevated source/drains, for example, an upper surface of the first source 120a and an upper surface of the first drain 121a may be formed at a plan higher than that of an upper surface of the first channel layer 110a, but the present inventive concept is not limited thereto. For example, unlike the case illustrated in some drawings, the upper surface of the first source 120a and the upper surface of the first drain 121a may be disposed on a plane substantially the same as that of the upper surface of the first channel layer 110a. The term “substantially” is meant to include process errors, measurement errors, and the like.

The first source 120a and the first drain 121a may include a material the same as that of the substrate 100 or a tensile stress material. For example, when the substrate 100 includes silicon (Si), the first source 120a and the first drain 121a may include silicon (Si) or a material having a lattice constant smaller than that of silicon (Si) (e.g., silicon carbide (SiC)). When silicon carbide (SiC) is included in the first source 120a and the first drain 121a, a tensile stress applied to the first channel layer 110a may be adjusted by adjusting the concentration of C in the silicon carbide (SiC).

The first gate structure G1 may include a first interfacial insulating film 130a, a first gate insulating film 150a, a first gate electrode 140a, and a first gate spacer 160a.

The first interfacial insulating film 130a may be disposed on the first channel layer 110a. For example, the first interfacial insulating film 130a may be disposed between the first channel layer 110a and the first gate insulating film 150a. In other words, a lower surface of the first interfacial insulating film 130a may be in contact with the first channel layer 110a, and an upper surface of the first interfacial insulating film 130a may be in contact with the lower surface of the first gate insulating film 150a. A sidewall of the first interfacial insulating film 130a may be in contact with the first gate spacer 160a. The first interfacial insulating film 130a may contain silicon oxide (SiO₂), but the present inventive concept is not limited thereto. The first interfacial insulating film 130a is illustrated in some drawings, but the present inventive concept is not limited thereto. For example, in the semiconductor device according to an exemplary embodiment of the present inventive concept, the first interfacial insulating film 130a may be omitted.

The first gate insulating film 150a may extend along the side wall of the first gate spacer 160a and the upper surface of the first interfacial insulating film 130a. Alternatively, in an exemplary embodiment of the present inventive concept in which the first interfacial insulating film 130a is omitted, the first gate insulating film 150a may extend along the side wall of the first gate spacer 160a and the upper surface of the first channel layer 110a.

The first gate insulating film 150a may include a material having a high dielectric constant. The material having the high dielectric constant may include a material having a dielectric constant greater than that of a silicon oxide layer, for example, having a dielectric constant of about 10 to about 25, and may include one or more of, for example, hafnium oxide (HfO₂), hafnium silicon oxide (HfSiO₄), lanthanum oxide (La₂O₃), lanthanum aluminum oxide (LaAlO₃), zirconium oxide (ZrO₂), zirconium silicon oxide (ZrSiO₄), tantalum oxide (Ta₂O₅), titanium oxide (TiO₂), barium strontium titanium oxide (BaSrTi₂O₆), barium titanium oxide (BaTiO₃), strontium titanium oxide (SrTiO₃), yttrium oxide (Y₂O₃), aluminum oxide (Al₂O₃), lead scandium tantalum oxide (Pb(Sc,Ta)O₃) or lead zinc niobate (Pb(Zn_{1/3}Nb_{2/3})O₃), but the present inventive concept is not limited thereto.

The first gate electrode 140a may be disposed over the lower surface of the first gate insulating film 150a and on the side wall of the first gate insulating film 150a.

The first gate electrode 140a may include a conductive material. For example, the first gate electrode 140a may include at least one of, for example, doped polysilicon (Si), titanium nitride (TiN), tantalum nitride (TaN), tungsten nitride (WN), titanium (Ti), tantalum (Ta), aluminum (Al), copper (Cu), and tungsten (W), but the present inventive concept is not limited thereto. Those having ordinary skill in the technical field of the present inventive concept may form the first gate electrode 140a, utilizing various materials as necessary.

The first gate electrode 140a is illustrated as being formed as a single film structure in some drawings, but the present inventive concept is not limited thereto. For example, the first gate electrode 140a may have a structure in which two or more metal layers are stacked. In other words, the first gate electrode 140a may include a work function adjusting metal layer, and a metal layer for filling a space formed by the work function adjusting metal layer. For example, the first work function adjusting metal layer may be formed on the first gate insulating film 150a, and the metal layer may be formed on the first work function adjusting metal layer to fill the space defined by the work function adjusting metal layer.

The first gate spacers 160a may be spaced apart from each other and disposed on side walls of the first gate electrode 140a. For example, the first gate spacers 160a may be disposed on both sides of the first interfacial insulating film 130a and on both sides of the first gate insulating film 150a.

The first gate spacer 160a may include, for example, silicon nitride (Si₃N₄), silicon oxynitride (SiON), silicon oxide (SiO₂), silicon oxycarbonitride (SiOCN), silicon carbonitride (SiCN), silicon boron nitride (SiBN) and combinations thereof, but the present inventive concept is not limited thereto.

Although the first gate spacer 160a is illustrated as a single film structure in some drawings, but the present inventive concept is not limited thereto. For example, the first gate spacer 160a may have a multi-film structure.

A first interlayer insulating film 170a may be disposed to cover the first source 120a, the first drain 121a, and the first gate structure G1.

The first interlayer insulating film 170a may include at least one of, for example, a low dielectric constant material, an oxide film, a nitride film, and an oxynitride film. The low dielectric constant material may be made up of, for example, Flowable Oxide (FOX), Tonen SilaZen (TOSZ), Undoped Silica Glass (USG), Borosilica Glass (BSG), PhosphoSilica Glass (PSG), Boro Phospho Silica Glass (BPSG), Plasma Enhanced Tetra Ethyl Ortho Silicate (PETEOS), Fluoride Silicate Glass (FSG), High Density Plasma (HDP) oxide, Plasma Enhanced Oxide (PEOX), Flowable CVD (FCVD) oxide or a combination thereof, but the present inventive concept is not limited thereto.

The second transistor TR2 according to an exemplary embodiment of the present inventive concept may include a second channel layer 110b, a second source 120b, a second drain 121b, a first buffer layer 122, a second buffer layer 123, a second gate structure G2, and a second interlayer insulating film 170b. The structures of the second gate structure G2 and the second interlayer insulating film 170b may be similar to the structures of the first gate structure G1 and the first interlayer insulating film 170a, respectively. For example, the second gate structure G2 may include a second interfacial insulating film 130b, a second gate insulating film 150b, a second gate electrode 140b, and a second gate spacer 160b. Description of the second gate structure G2 and the second interlayer insulating film 170b will not be provided for convenience of explanation. However, a work function of the first gate structure G1 may be different from a work function of the second gate structure G2.

The second channel layer 110b may be disposed on the first PMOS region P1 of the substrate 100, and may have a shape protruding from the first PMOS region P1 of the substrate 100. The second channel layer 110b may be a path through which carriers move from the second source 120b to the second drain 121b. For example, the second transistor TR2 formed on the first PMOS region P1 of the substrate 100 may be a PMOS transistor, and the carriers moving from the second source 120b to the second drain 121b may be holes. In other words, electrons are moving from the second drain 121b to the second source 120b.

The second channel layer 110b may include a first material, and the first material may be silicon (Si), but the present inventive concept is not limited thereto. For example, the first channel layer 110a and the second channel layer 110b may include the same first material such as, for example, silicon (Si).

Although an angle formed between the second channel layer 110b and the first PMOS region P1 of the substrate 100 is illustrated as a right angle in some of the drawings, the present inventive concept is not limited thereto. For example, the second channel layer 110b may have a tapered shape and/or may have a chamfered rectangular shape. Those having ordinary skill in the technical field of the present inventive concept may form the second channel layer 110b in various ways.

The second source 120b and the second drain 121b may be disposed on the first PMOS region P1 of the substrate 100, and may be disposed on both sides of the second channel layer 110b.

The second source 120b and the second drain 121b may be elevated source/drains, for example, an upper surface of the second source 120b and an upper surface of the second drain 121b may be formed at a plane higher than that of an upper surface of the second channel layer 110b, but the present inventive concept is not limited thereto. For example, unlike the case illustrated in some drawings, the upper surface of the second source 120b and the upper surface of the second drain 121b may be disposed on a plan substantially the same as that of the upper surface of the second channel layer 110b.

The second source 120b and the second drain 121b may include compressive stress materials. The compressive stress materials may be materials having a lattice constant greater than silicon (Si) such as, for example, silicon germanium (SiGe). For example, the second source 120b and the second drain 121b may include silicon germanium (SiGe), but the present inventive concept is not limited thereto. However, it is assumed that each of the second source 120b and the second drain 121b contains silicon germanium (SiGe) in the following description for convenience of explanation. The compressive stress material may enhance the carrier mobility within the second channel layer 110b, by applying compressive stress to the second channel layer 110b. It should be understood that by adjusting the concentrations of the germanium (Ge) content in the second source 120b and the second drain 121b, the compressive stresses applied to the second channel layer 110b may be adjusted. In general, the film compressive stress increases with the increase of the germanium (Ge) concentration.

The first buffer layer 122 may be disposed between the second channel layer 110b and the second source 120b. The first buffer layer 122 may include, for example, silicon germanium (SiGe). A first concentration of germanium (Ge) contained in the second source 120b may be greater than a second concentration of germanium (Ge) contained in the first buffer layer 122. In other words, the first buffer layer 122 and the second source 120b contain silicon germanium (SiGe), and the concentration of germanium (Ge) of the first buffer layer 122 may be smaller than the concentration of germanium (Ge) of the second source 120b.

The second buffer layer 123 may be disposed between the second channel layer 110b and the second drain 121b. The second buffer layer 123 may include silicon germanium (SiGe). A third concentration of germanium (Ge) contained in the second drain 121b may be greater than a fourth concentration of germanium (Ge) contained in the second buffer layer 123. In other words, the second buffer layer 123 and the second drain 121b contain silicon germanium (SiGe), and the concentration of germanium (Ge) of the second buffer layer 123 may be smaller than the concentration of germanium (Ge) of the second drain 121b.

The third transistor TR3 according to an exemplary embodiment of the present inventive concept may be disposed on the second PMOS region P2 of the substrate 100. The third transistor TR3 may include a third channel layer 110c, a third source 120c, a third drain 121c, a third gate structure G3, and a third interlayer insulating film 170c. The structures relating to the third source 120c, the third drain 121c, the third gate structure G3, and the third interlayer insulating film 170c may be similar to the structures relating to the second source 120b, the second drain 121b, the second gate structure G2, and the second interlayer insulating film 170b, respectively. For example, the third gate structure G3 may include a third interfacial insulating film 130c, a third gate insulating film 150c, a third gate electrode 140c, and a third gate spacer 160c. For convenience of explanation, descriptions of the third source 120c, the third drain 121c, the third gate structure G3, and the third interlayer insulating film 170c will not be provided.

The third channel layer 110c may be disposed on the second PMOS region P2 of the substrate 100, and may have a shape protruding from the second PMOS region P2 of the substrate 100. The third channel layer 110c may be a path through which carriers move from the third source 120c to the third drain 121c. For example, the third transistor TR3 formed on the second PMOS region P2 of the substrate 100 may be an PMOS transistor, and the carriers moving from the third source 120c to the third drain 121c may be holes. In other words, electrons are moving from the third drain 121c to the third source 120c.

The third channel layer 110c may include a second material different from the first material contained in the first channel layer 110a and the second channel layer 110b. For example, the second material may be silicon germanium (SiGe), but the present inventive concept is not limited thereto. Silicon germanium (SiGe) channel has excellent mobility compared to silicon (Si) channel and has excellent current performance in On state. However, silicon germanium (SiGe) has weak energy bandgap compared to silicon (Si), and leakage due to band to band tunneling is weak. In an exemplary embodiment of the present inventive concept, a silicon germanium (SiGe) channel transistor (e.g., the third transistor TR3) may be selectively used in a region (e.g., the second PMOS region P2 of the substrate 100) where a high-performance transistor is required when designing a chip, and a silicon (Si) channel transistor (e.g., the second transistor TR2) may be used to effectively control the performance enhancement and the leakage.

Although an angle formed between the third channel layer 110c and the second PMOS region P2 of the substrate 100 is illustrated as a right angle in some of the drawings, the present inventive concept is not limited thereto. For example, the third channel layer 110c may have a tapered shape and/or may have a chamfered rectangular shape. Those having ordinary skill in the technical field of the present inventive concept may form the third channel layer 110c in various ways.

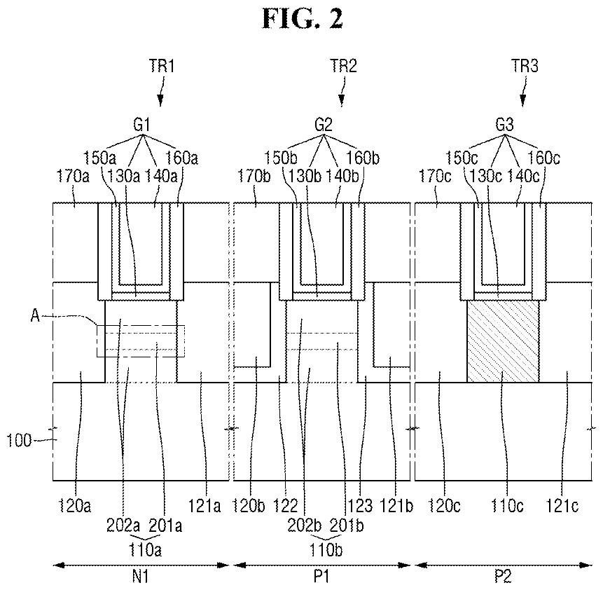

FIG. 2 is a cross-sectional view illustrating a semiconductor device according to an exemplary embodiment of the present inventive concept. For convenience of explanation, repeated or similar contents of the above-described contents will not be explained or will be briefly explained.

Referring to FIG. 2, the semiconductor device according to an exemplary embodiment of the present inventive concept may include a first transistor TR1, a second transistor TR2, and a third transistor TR3.

In an exemplary embodiment of the present inventive concept, the first transistor TR1 may be disposed on the first NMOS region N1 of the substrate 100, and may include a first channel layer 110a, a first source 120a, a first drain 121a, a first gate structure G1, and a first interlayer insulating film 170a.

The first channel layer 110a may include a first impurity region 201a and a second impurity region 202a. The first impurity region 201a may be a region in which concentration of a first impurity is equal to or higher than a first concentration. The second impurity region 202a may be a region in which concentration of the first impurity is lower than the first concentration. The first impurity region 201a may be disposed between the second impurity regions 202a.

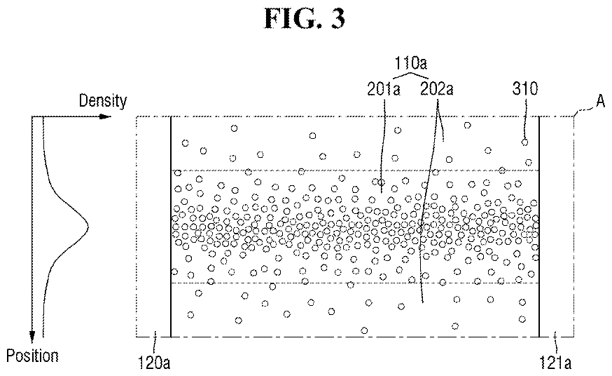

The first impurity region 201a and the second impurity region 202a may be formed through an ion implantation process and an annealing process, but the present inventive concept is not limited thereto. For example, the first impurity region 201a and the second impurity region 202a may be formed through diffusion. For a detailed description of the first impurity region 201a and the second impurity region 202a, description will be made with reference to FIG. 3.

FIG. 3 is an enlarged cross-sectional view of “A” region of FIG. 2 for illustrating a first impurity region and a second impurity region according to an exemplary embodiment of the present inventive concept.

Referring to FIG. 3, first impurity 310 may be implanted into the first channel layer 110a by an ion implantation process. Those having ordinary skill in the technical field of the present inventive concept may implant the first impurity 310 to a desired depth, using an appropriate method. At this time, the first impurity 310 may be randomly distributed in the first channel layer 110a. For example, the first impurity 310 may be distributed in accordance with a normal distribution in the first channel layer 110a. Hereinafter, as described above, for convenience of description, a region in which the concentration of the first impurity 310 is equal to or higher than the first concentration is referred to as a first impurity region 201a. Further, a region in which the concentration of the first impurity 310 is lower than the first concentration is referred to as a second impurity region 202a. Since the first impurity 310 is distributed in the first channel layer 110a in accordance with a normal distribution, the first impurity region 201a may have an apex disposed between the second impurity regions 202a. The first concentration of the first impurity 310 may be defined as the lowest concentration at three standard deviation away from the mean of the normal distribution of the first impurity 310, but the present inventive concept is not limited thereto. For example, the first concentration may be defined as the lowest concentration at two standard deviation away from the mean of the normal distribution, or any other suitable concentration to define the regions of the first impurity region 201a and the second impurity region 202a.

Referring again to FIG. 2, the second transistor TR2 according to an exemplary embodiment of the present inventive concept may be disposed on the first PMOS region P1 of the substrate 100. The second transistor TR2 may include a second channel layer 110b, a second source 120b, a second drain 121b, a second gate structure G2, and a second interlayer insulating film 170b.

The second channel layer 110b may include a third impurity region 201b and a fourth impurity region 202b. The third impurity region 201b may be disposed between the fourth impurity regions 202b. The third impurity region 201b and the fourth impurity region 202b may be similar to the first impurity region 201a and the second impurity region 202a described above with reference to FIG. 3. For example, the third impurity region 201b may be a region in which concentration of a second impurity is equal to or higher than a second concentration. In addition, the fourth impurity region 202b may be a region in which concentration of the second impurity is lower than the second concentration. For example, the third impurity region 201b and the fourth impurity region 202b may be formed through an ion implantation process, but the present inventive concept is not limited thereto. Since the second impurity may be distributed in the second channel layer 110b in accordance with a normal distribution, the third impurity region 201b may have an apex disposed between the fourth impurity regions 202b. The second concentration of the second impurity may be defined as the lowest concentration at three standard deviation away from the mean of the normal distribution of the second impurity, but the present inventive concept is not limited thereto. For example, the second concentration may be defined as the lowest concentration at two standard deviation away from the mean of the normal distribution, or any other suitable concentration to define the regions of the third impurity region 201b and the fourth impurity region 202b.

The first impurity region 201a and the third impurity region 201b according to an exemplary embodiment of the present inventive concept may be used to adjust a threshold voltage of the first transistor TR1 and the second transistor TR2, respectively.

The semiconductor device described with reference to FIGS. 2 and 3 may be similar to the semiconductor device of FIG. 1, except that the first channel layer 110a includes a first impurity region 201a and a second impurity region 202a, and the second channel layer 110b includes a third impurity region 201b and a fourth impurity region 202b. Therefore, a first source 120a, a first drain 121a, a first gate structure G1, a first interlayer insulating film 170a, a second source 120b, a second drain 121b, a second gate structure G2, a second interlayer insulating film 170b, a third source 120c, a third drain 121c, a third gate structure G3, and a third interlayer insulating film 170c will not be explained.

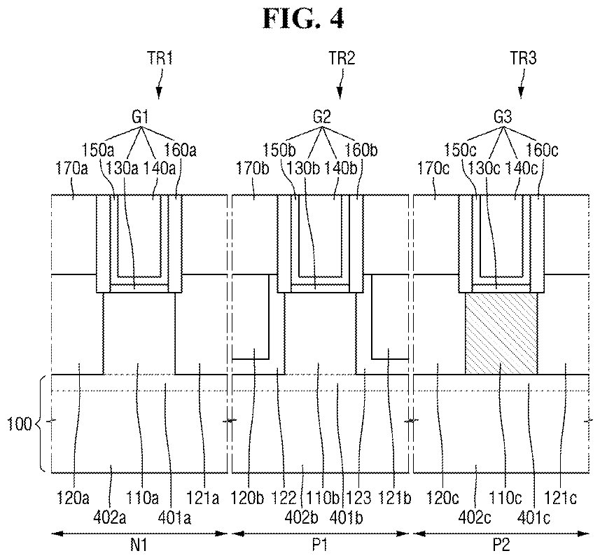

FIG. 4 is a cross-sectional view illustrating a semiconductor device according to an exemplary embodiment of the present inventive concept. For convenience of explanation, repeated or similar contents will not be explained or will be briefly explained.

Referring to FIG. 4, the semiconductor device according to an exemplary embodiment of the present inventive concept may include a first transistor TR1, a second transistor TR2, and a third transistor TR3.

The first transistor TR1 according to an exemplary embodiment of the present inventive concept may be arranged on the first NMOS region N1 of the substrate 100. Further, the second transistor TR2 may be disposed on the first PMOS region P1 of the substrate 100. Further, the third transistor TR3 may be disposed on the second PMOS region P2 of the substrate 100. In other words, the first transistor TR1 may be an NMOS transistor. Further, the second transistor TR2 and the third transistor TR3 may be PMOS transistors.

The substrate 100 according to an exemplary embodiment of the present inventive concept may include a fifth impurity region 401a, a sixth impurity region 402a, a seventh impurity region 401b, an eighth impurity region 402b, a ninth impurity region 401c, and a tenth impurity region 402c. For example, the first NMOS region N1 of the substrate 100 may include the fifth impurity region 401a and the sixth impurity region 402a. Further, for example, the first PMOS region P1 of the substrate 100 may include the seventh impurity region 401b and the eighth impurity region 402b. Further, for example, the second PMOS region P2 of the substrate 100 may include the ninth impurity region 401c and the tenth impurity region 402c.

In the same manner as described above, the fifth impurity region 401a may be a region in which concentration of a third impurity is equal to or greater than a third concentration. The sixth impurity region 402a may be a region in which concentration of the third impurity is lower than the third concentration. The seventh impurity region 401b may be a region in which concentration of a fourth impurity is equal to or greater than a fourth concentration. The eighth impurity region 402b may be a region in which concentration of the fourth impurity is lower than the fourth concentration. The ninth impurity region 401c may be a region in which concentration of a fifth impurity is equal to or greater than a fifth concentration. The tenth impurity region 402c may be a region in which concentration of the fifth impurity is lower than the fifth concentration. The third to fifth concentrations may be defined similar to the first and second concentrations described above. The conductivity type of the third impurity may be different from that of the fourth impurity and the fifth impurity.

According to an exemplary embodiment of the present inventive concept, the fifth impurity region 401a may be disposed on the lower surfaces of the first source 120a and the first drain 121a. Further, the fifth impurity region 401a may be disposed below the first channel layer 110a. The seventh impurity region 401b may be disposed on the lower surfaces of the second source 120b and the second drain 121b. Further, the seventh impurity region 401b may be disposed below the second channel layer 110b. The ninth impurity region 401c may be disposed on the lower surfaces of the third source 120c and the third drain 121c. Further, the ninth impurity region 401c may be disposed below the third channel layer 110c.

According to an exemplary embodiment of the present inventive concept, the fifth impurity region 401a may prevent punch-through between the first source 120a and the first drain 121a. Further, the seventh impurity region 401b may prevent punch-through between the second source 120b and the second drain 121b. Further, the ninth impurity region 401c may prevent punch-through between the third source 120c and the third drain 121c. The fifth impurity region 401a may have a conductivity type different from that of the first source 120a and the first drain 121a. Further, the seventh impurity region 401b may have a conductivity type different from that of the second source 120b and the second drain 121b. Further, the ninth impurity region 401c may have a conductivity type different from that of the third source 120c and the third drain 121c.

The semiconductor device described with reference to FIG. 4 may be similar to the semiconductor device of FIG. 1 except that the substrate 100 includes the fifth to tenth impurity regions 401a, 402a, 401b, 402b, 401c and 402c. Therefore, a first channel layer 110a, a first source 120a, a first drain 121a, a first gate structure G1, a first interlayer insulating film 170a, a second channel layer 110b, a second source 120b, a second drain 121b, a first buffer layer 122, a second buffer layer 123, a second gate structure G2, a second interlayer insulating film 170b, a third channel layer 110c, a third source 120c, a third drain 121c, a third gate structure G3, and a third interlayer insulating film 170c of FIG. 4 will not be described.

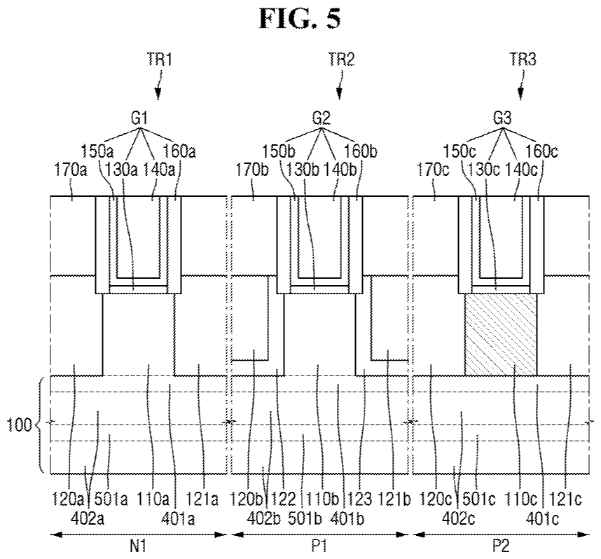

FIG. 5 is a cross-sectional view for describing a semiconductor device according to an exemplary embodiment of the present inventive concept. For convenience of explanation, repeated or similar contents will not be explained or will be briefly explained.

Referring to FIG. 5, the semiconductor device according to an exemplary embodiment of the present inventive concept may include a first transistor TR1, a second transistor TR2, and a third transistor TR3.

The first transistor TR1 according to an exemplary embodiment of the present inventive concept may be disposed on the first NMOS region N1 of the substrate 100. Further, the second transistor TR2 may be disposed on the first PMOS region P1 of the substrate 100. Further, the third transistor TR3 may be disposed on the second PMOS region P2 of the substrate 100. In other words, the first transistor TR1 may be an NMOS transistor. Further, the second transistor TR2 and the third transistor TR3 may be PMOS transistors.

The substrate 100 according to an exemplary embodiment of the present inventive concept may include a fifth impurity region 401a, a sixth impurity region 402a, a seventh impurity region 401b, an eighth impurity region 402b, a ninth impurity region 401c, a tenth impurity region 402c, an eleventh impurity region 501a, a twelfth impurity region 501b, and a thirteenth impurity region 501c.

As described above, the fifth impurity region 401a and the eleventh impurity region 501a may be regions in which the concentration of the third impurity is equal to or greater than the third concentration. Further, the sixth impurity region 402a may be a region in which the concentration of the third impurity is lower than the third concentration. The seventh impurity region 401b and the twelfth impurity region 501b may be regions in which the concentration of the fourth impurity is equal to or greater than the fourth concentration. The eighth impurity region 402b may be a region in which the concentration of the fourth impurity is lower than the fourth concentration. The ninth impurity region 401c and the thirteenth impurity region 501c may be regions in which the concentration of the fifth impurity is equal to or greater than the fifth concentration. The tenth impurity region 402c may be a region in which the concentration of the fifth impurity is lower than the fifth concentration.

According to an exemplary embodiment of the present inventive concept, the eleventh impurity region 501a may be spaced apart from the fifth impurity region 401a, and may be disposed below the lower surface of the fifth impurity region 401a. In other words, the sixth impurity region 402a may be disposed between the fifth impurity region 401a and the eleventh impurity region 501a. Further, the sixth impurity region 402a may also be disposed below the lower surface of the eleventh impurity region 501a.

The twelfth impurity region 501b may be spaced apart from the seventh impurity region 401b, and may be disposed below the lower surface of the seventh impurity region 401b. In other words, the eighth impurity region 402b may be disposed between the seventh impurity region 401b and the twelfth impurity region 501b. Further, the eighth impurity region 402b may also be disposed below the lower surface of the twelfth impurity region 501b.

The thirteenth impurity region 501c may be spaced apart from the ninth impurity region 401c, and may be disposed below the lower surface of the ninth impurity region 401c. In other words, the tenth impurity region 402c may be disposed between the ninth impurity region 401c and the thirteenth impurity region 501c. Further, the tenth impurity region 402c may also be disposed below the lower surface of the thirteenth impurity region 501c.

According to an exemplary embodiment of the present inventive concept, the eleventh impurity region 501a may insulate between the first source 120a, the first drain 121a and the body of the first transistor TR1. In addition, the twelfth impurity region 501b may insulate between the second source 120b, the second drain 121b and the body of the second transistor TR2. The thirteenth impurity region 501c may insulate between the third source 120c, the third drain 121c and the body of the third transistor TR3.

The semiconductor device described referring to FIG. 5 may be similar to the semiconductor device of FIG. 4, except that the substrate 100 further includes an eleventh impurity region 501a, a twelfth impurity region 501b, and a thirteenth impurity region 501c. Therefore, a first channel layer 110a, a first source 120a, a first drain 121a, a first gate structure G1, a first interlayer insulating film 170a, a second channel layer 110b, a second source 120b, a second drain 121b, a first buffer layer 122, a second buffer layer 123, a second gate structure G2, a second interlayer insulating film 170b, a third channel layer 110c, a third source 120c, a third drain 121c, a third gate structure G3, and a third interlayer insulating film 170c of FIG. 5 will not be explained.

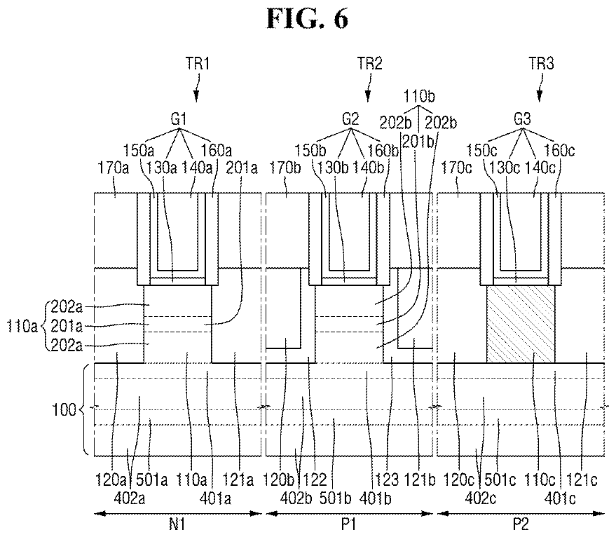

FIG. 6 is a cross-sectional view illustrating a semiconductor device according to an exemplary embodiment of the present inventive concept. For convenience of explanation, repeated or similar contents will not be explained or will be briefly explained.

Referring to FIG. 6, the semiconductor device according to an exemplary embodiment of the present inventive concept may include a first transistor TR1, a second transistor TR2, and a third transistor TR3.

The first transistor TR1 according to an exemplary embodiment of the present inventive concept may be disposed on the first NMOS region N1 of the substrate 100. Further, the second transistor TR2 may be disposed on the first PMOS region P1 of the substrate 100. In addition, the third transistor TR3 may be disposed on the second PMOS region P2 of the substrate 100. In other words, the first transistor TR1 may be an NMOS transistor. In addition, the second transistor TR2 and the third transistor TR3 may be PMOS transistors.

According to an exemplary embodiment of the present inventive concept, the first channel layer 110a may include a first impurity region 201a and a second impurity region 202a. The second channel layer 110b may include a third impurity region 201b and a fourth impurity region 202b. The substrate 100 may include a fifth impurity region 401a through a thirteenth impurity region 501c. Since the first impurity region 201a through the thirteenth impurity region 501c of FIG. 6 are similar to the contents described above, a detailed description thereof will not be provided.

The semiconductor device described with reference to FIG. 6 may be similar to the semiconductor device of FIG. 5, except that the first channel layer 110a includes a first impurity region 201a and a second impurity region 202a, and the second channel layer 110b includes a third impurity region 201b and a fourth impurity region 202b. The first impurity region 201a, the second impurity region 202a, the third impurity region 201b and the fourth impurity region 202b are as described with reference to the semiconductor device of FIG. 2 above. Thus, a first source 120a, a first drain 121a, a first gate structure G1, a first interlayer insulating film 170a, a second source 120b, a second drain 121b, a first buffer layer 122, a second buffer layer 123, a second gate structure G2, a second interlayer insulating film 170b, a third source 120c, a third drain 121c, a third gate structure G3, and a third interlayer insulating film 170c of FIG. 6 will not be described.

According to an exemplary embodiment of the present inventive concept, in the semiconductor device described with reference to FIG. 6, the first impurity region 201a and the third impurity region 201b may be used to adjust a threshold voltage of the first transistor TR1 and the second transistor TR2, respectively. The fifth impurity region 401a may prevent punch-through between the first source 120a and the first drain 121a. The seventh impurity region 401b may prevent punch-through between the second source 120b and the second drain 121b. The ninth impurity region 401c may prevent punch-through between the third source 120c and the third drain 121c. Further, the eleventh impurity region 501a may insulate between the first source 120a, the first drain 121a and the body of the first transistor TR1. Further, the twelfth impurity region 501b may insulate between the second source 120b, the second drain 121b and the body of the second transistor TR2. In addition, the thirteenth impurity region 501c may insulate between the third source 120c, the third drain 121c and the body of the third transistor TR3.

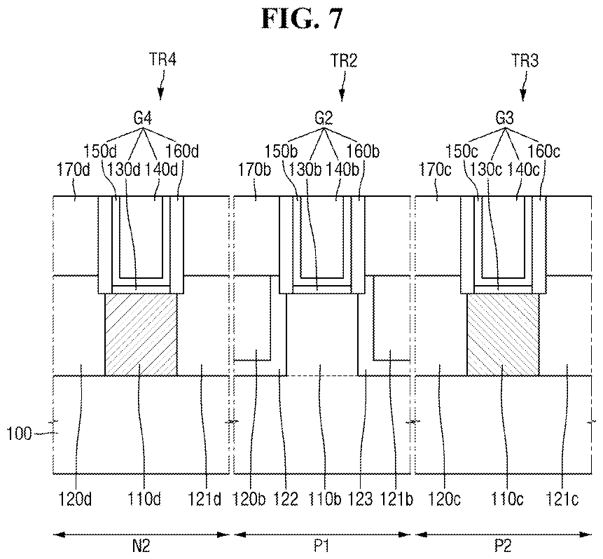

FIG. 7 is a cross-sectional view for explaining a semiconductor device according to an exemplary embodiment of the present inventive concept. For convenience of explanation, repeated or similar contents will not be explained or will be briefly explained.

Referring to FIG. 7, the semiconductor device according to an exemplary embodiment of the present inventive concept may include a second transistor TR2, a third transistor TR3, and a fourth transistor TR4.

The second transistor TR2 according to an exemplary embodiment of the present inventive concept may be disposed on the first PMOS region P1 of the substrate 100. Further, the third transistor TR3 may be disposed on the second PMOS region P2 of the substrate 100. Further, the fourth transistor TR4 may be disposed on the second NMOS region N2 of the substrate 100. In other words, the second transistor TR2 and the third transistor TR3 may be PMOS transistors. In addition, the fourth transistor TR4 may be an NMOS transistor.

According to an exemplary embodiment of the present inventive concept, the driving current when the fourth transistor TR4 is turned on may be greater than the driving current when the first transistor TR1 described above is turned on. Thus, the fourth transistor TR4 may have a performance higher than that of the first transistor TR1. In an exemplary embodiment of the present inventive concept, the leakage current of the fourth transistor TR4 may be greater than the leakage current of the first transistor TR1 described above.

The second transistor TR2 according to an exemplary embodiment of the present inventive concept may include a second channel layer 110b, a second source 120b, a second drain 121b, a first buffer layer 122, a second buffer layer 123, a second gate structure G2, and a second interlayer insulating film 170b. Further, the third transistor TR3 may include a third channel layer 110c, a third source 120c, a third drain 121c, a third gate structure G3, and a third interlayer insulating film 170c. Further, the fourth transistor TR4 may include a fourth channel layer 110d, a fourth source 120d, a fourth drain 121d, a fourth gate structure G4, and a fourth interlayer insulating film 170d. For example, the fourth gate structure G4 may include a fourth interfacial insulating film 130d, a fourth gate insulating film 150d, a fourth gate electrode 140d, and a fourth gate spacer 160d.

According to an exemplary embodiment of the present inventive concept, the second channel layer 110b may include a first material. For example, the first material may be silicon (Si), but the present inventive concept is not limited thereto. According to an exemplary embodiment of the present inventive concept, the third channel layer 110c may include a second material different from the first material. For example, the second material may be silicon germanium (SiGe), but the present inventive concept is not limited thereto. Silicon germanium (SiGe) may provide hole mobility enhancement. According to an exemplary embodiment of the present inventive concept, the fourth channel layer 110d may include a third material different from the first material and the second material. For example, the third material may be silicon carbide (SiC), but the present inventive concept is not limited thereto. Silicon carbide (SiC) may provide electron mobility enhancement. In other words, the second channel layer 110b, the third channel layer 110c and the fourth channel layer 110d may contain materials different from each other.

The fourth transistor TR4 may be similar to the first transistor TR1 of FIG. 1 except that the fourth channel layer 110d contains a third material. Therefore, a fourth source 120d, a fourth drain 121d, a fourth gate structure G4 and a fourth interlayer insulating film 170d will not be explained.

In an exemplary embodiment of the present inventive concept, a silicon carbide (SiC) channel transistor (e.g., the fourth transistor TR4) is selectively used in a region (e.g., the second NMOS region N2 of the substrate 100) where a high-performance transistor is required when designing a chip, and a silicon (Si) channel transistor (e.g., the first transistor TR1) is used to effectively control the performance enhancement and the leakage.

FIG. 8 is a cross-sectional view illustrating a semiconductor device according to an exemplary embodiment of the present inventive concept. For convenience of explanation, repeated or similar contents will not be explained or will be briefly explained.

Referring to FIG. 8, the semiconductor device according to an exemplary embodiment of the present inventive concept may include a first transistor TR1, a second transistor TR2, a third transistor TR3, and a fourth transistor TR4.

The semiconductor device according to an exemplary embodiment of the present inventive concept may include the first transistor TR1, the second transistor TR2 and the third transistor TR3 described with reference to FIG. 1, and the fourth transistor TR4 described with reference to FIG. 7. For convenience of explanation, the description of the first to fourth transistors TR1 to TR4 will not be provided. In the semiconductor device according to an exemplary embodiment of the present inventive concept described with reference to FIG. 8, the third transistor TR3 may have a performance higher than that of the second transistor TR2, and the fourth transistor TR4 may have a performance higher than that of the first transistor TR1. For example, the first transistor TR1 may be a general NMOS transistor, the second transistor TR2 may be a general PMOS transistor, the third transistor TR3 may be a high-performance PMOS transistor, and the fourth transistor TR4 may be a high-performance NOMS transistor.

Although the semiconductor device according to an exemplary embodiment of the present inventive concept has been described with reference to FIGS. 1 to 8, the present inventive concept is not limited thereto. Those having ordinary skill in the technical field of the present inventive concept may implement the semiconductor device including the first transistor TR1, the second transistor TR2, the third transistor TR3, and/or the fourth transistor TR4 with various combinations.

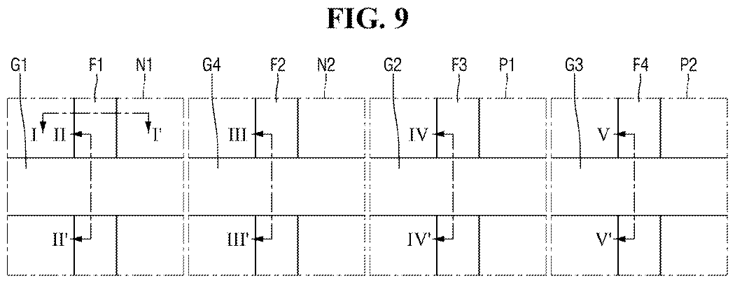

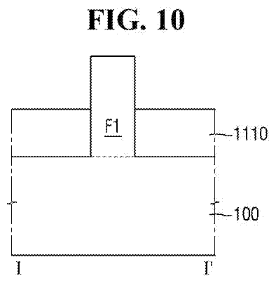

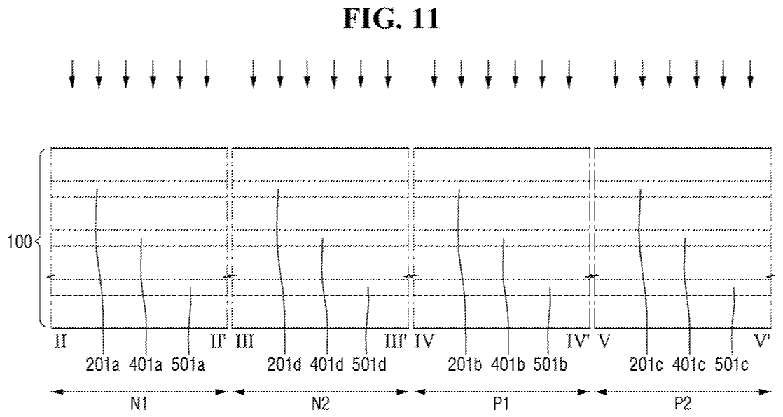

FIG. 9 is a layout diagram for explaining a semiconductor device according to an exemplary embodiment of the present inventive concept. FIG. 10 is a cross-sectional view taken along line I-I′ of FIG. 9. FIGS. 11 to 17 are intermediate step cross-sectional views for explaining a method of fabricating a semiconductor device according to an exemplary embodiment of the present inventive concept.

Referring to FIGS. 9 and 10, a first fin-type pattern F1, a second fin-type pattern F2, a third fin-type pattern F3, and a fourth fin-type F4 are formed on the substrate 100, respectively. The first fin-type pattern F1, the second fin-type pattern F2, the third fin-type pattern F3, and the fourth fin-type pattern F4 may be formed by recessing the substrate 100, but the present inventive concept is not limited thereto. For example, in an exemplary embodiment of the present inventive concept, the first fin-type pattern F1, the second fin-type pattern F2, the third fin-type pattern F3, and the fourth fin-type F4 may be formed by epitaxy growth of the first fin-type pattern F1, the second fin-type pattern F2, the third fin-type pattern F3, and the fourth fin-type pattern F4 on the substrate 100.

A field insulating film 1110 which covers at least a part of the first fin-type pattern F1 is formed. In addition, the field insulating film 1110 may also be formed to cover the second fin-type pattern F2, the third fin-type pattern F3, and the fourth fin-type pattern F4.

Referring to FIG. 11, a first impurity region 201a through a thirteenth impurity region 501c, a fourteenth impurity region 201d, a fifteenth impurity region 401d, a sixteenth impurity region 501d, and a seventeenth impurity region 201c may be formed in the substrate 100, using an ion implantation process and an annealing process. The fourteenth impurity region 201d may be similar to the first impurity region 201a. The seventeenth impurity region 201c may be similar to the third impurity region 201b. Further, the fifteenth impurity region 401d may be similar to the fifth impurity region 401a. Also, the sixteenth impurity region 501d may be similar to the eleventh impurity region 501a. Although the ion implantation process is used as an example when forming the first impurity region 201a through the thirteenth impurity region 501c in this specification, the present inventive concept is not limited thereto. Those having ordinary skill in the technical field of the present inventive concept may form the first impurity region 201a through the seventeenth impurity region 201c by various methods.

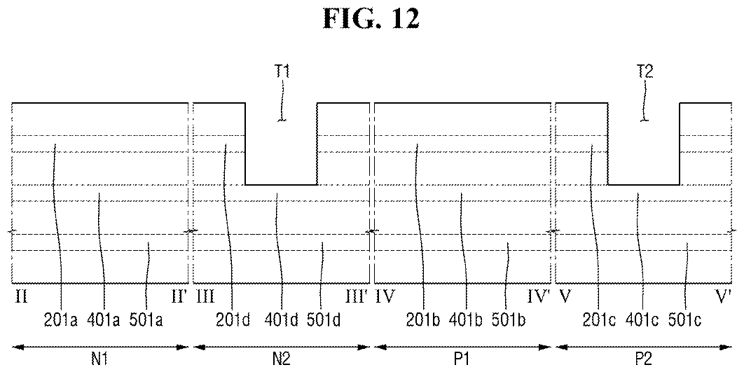

Referring to FIG. 12, a first trench T1 and a second trench T2 are formed, respectively. For example, at least a part of the second NMOS region N2 of the substrate 100 may be recessed to form the first trench T1. Further, for example, at least a part of the second PMOS region P2 of the substrate 100 may be recessed to form the second trench T2.

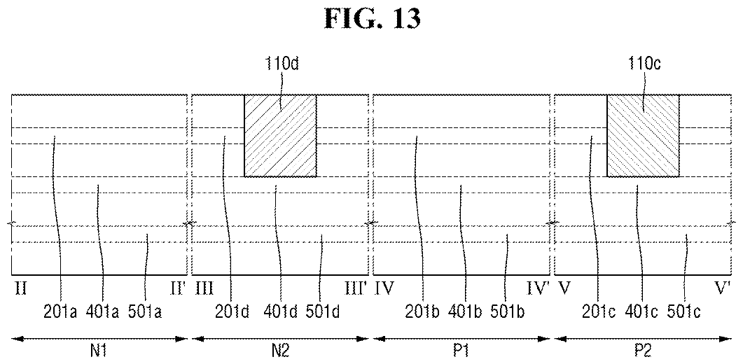

Referring to FIGS. 12 and 13, a fourth channel layer 110d and a third channel layer 110c may be formed in the first trench T1 and the second trench T2, respectively. According to an exemplary embodiment of the present inventive concept, the fourth channel layer 110d and the third channel layer 110c may be formed using an epitaxial growth process, a chemical vapor deposition (CVD) process and/or a physical vapor deposition (PVD) process, but the present inventive concept is not limited thereto. Those having ordinary skill in the technical field of the present inventive concept may form the fourth channel layer 110d and the third channel layer 110c in various ways. As described above, the fourth channel layer 110d may include a third material (e.g., silicon carbide (SiC)), and the third channel layer 110c may include a second material (e.g., silicon germanium (SiGe)).

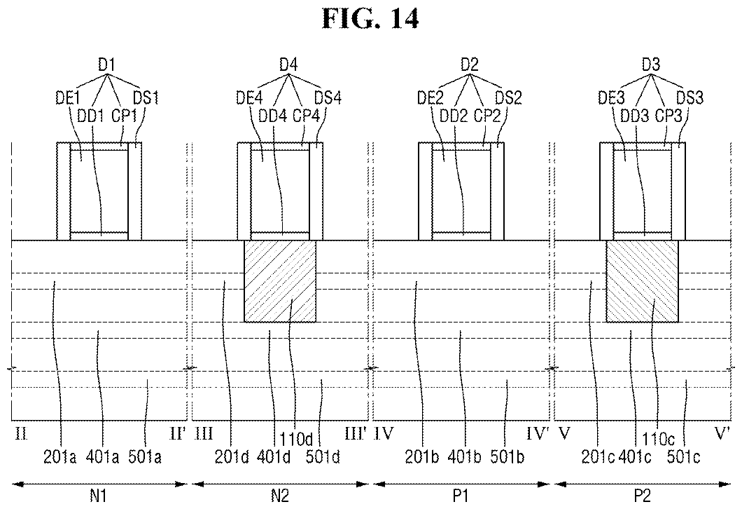

Referring to FIG. 14, a first dummy gate structure D1, a second dummy gate structure D2, a third dummy gate structure D3, and a fourth dummy gate structure D4 may be formed on the substrate 100. For example, the first dummy gate structure D1 may be formed on the first NMOS region N1 of the substrate 100. For example, the second dummy gate structure D2 may be formed on the first PMOS region P1 of the substrate 100. For example, the third dummy gate structure D3 may be formed on the second PMOS region P2 of the substrate 100. For example, the fourth dummy gate structure D4 may be formed on the second NMOS region N2 of the substrate 100.

According to an exemplary embodiment of the present inventive concept, the first dummy gate structure D1 may include a first dummy gate insulating film DD1, a first dummy gate electrode DE1, a first dummy gate spacer DS1, and a first capping film CP1, but the present inventive concept is not limited thereto. In addition, the second dummy gate structure D2 may include a second dummy gate insulating film DD2, a second dummy gate electrode DE2, a second dummy gate spacer DS2, and a second capping film CP2, but the present inventive concept is not limited thereto. In addition, the third dummy gate structure D3 may include a third dummy gate insulating film DD3, a third dummy gate electrode DE3, a third dummy gate spacer DS3, and a third capping film CP3, but the present inventive concept is not limited thereto. Further, the fourth dummy gate structure D4 may include a fourth dummy gate insulating film DD4, a fourth dummy gate electrode DE4, a fourth dummy gate spacer DS4, and a fourth capping film CP4, but the present inventive concept is not limited thereto.

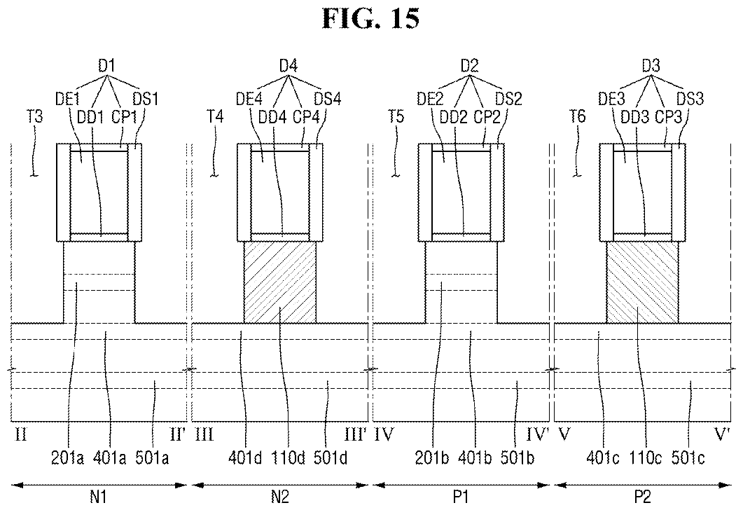

Referring to FIG. 15, the third trench T3, the fourth trench T4, the fifth trench T5, and the sixth trench T6 are formed, using the first dummy gate structure D1 through the fourth dummy gate structure D4. For example, the third to sixth trenches T3 to T6 may be formed by an etching process using the first to fourth dummy gate structures D1 to D4 as an etch mask to etch the substrate 100.

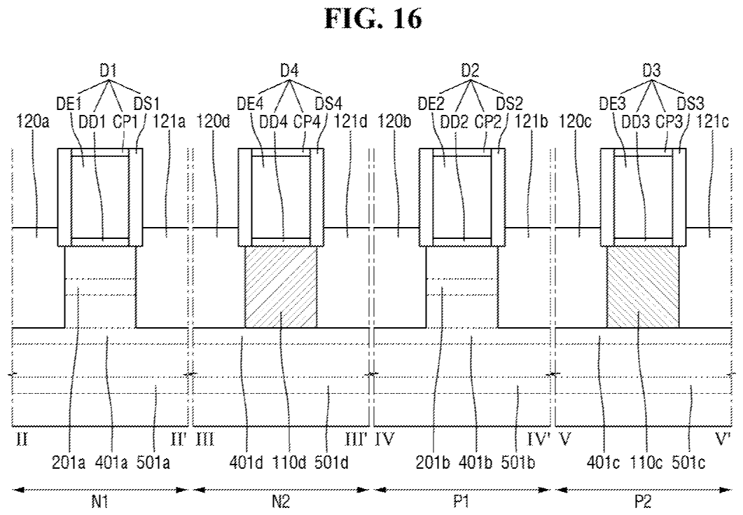

Referring to FIG. 16, the first source 120a and the first drain 121a may be formed by filling the third trench T3. Further, the second source 120b and the second drain 121b may be formed by filling the fifth trench T5. Further, the third source 120c and the third drain 121c may be formed by filling the sixth trench T6. Further, the fourth source 120d and the fourth drain 121d may be formed by filling the fourth trench T4. According to an exemplary embodiment of the present inventive concept, the first source 120a, the first drain 121a, the second source 120b, the second drain 121b, the third source 120c, the third drain 121c, the fourth source 120d, and the fourth drain 121d may each be formed using an epitaxial growth process, a chemical vapor deposition (CVD) process and/or a physical vapor deposition (PVD) process, but the present inventive concept is not limited thereto.

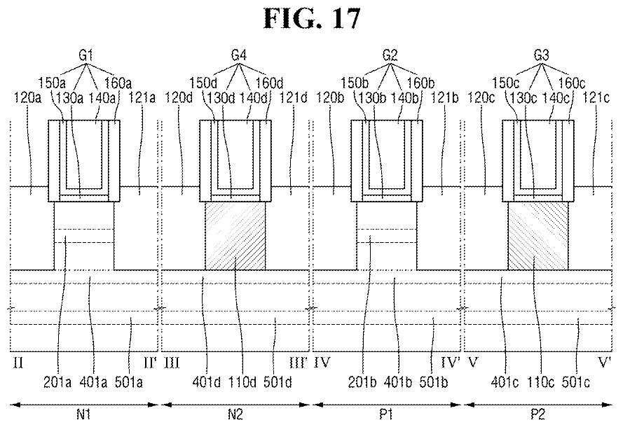

Referring to FIG. 17, the first dummy gate structure D1 through the fourth dummy gate structure D4 are removed, and the first gate structure G1 through the fourth gate structure G4 are formed.

Although a method of fabricating a semiconductor device using a gate last process has been described with reference to FIGS. 11 to 17, the present inventive concept is not limited thereto. For example, it is a matter of course that the semiconductor device of FIGS. 1 to 8 may be fabricated using a gate first process.

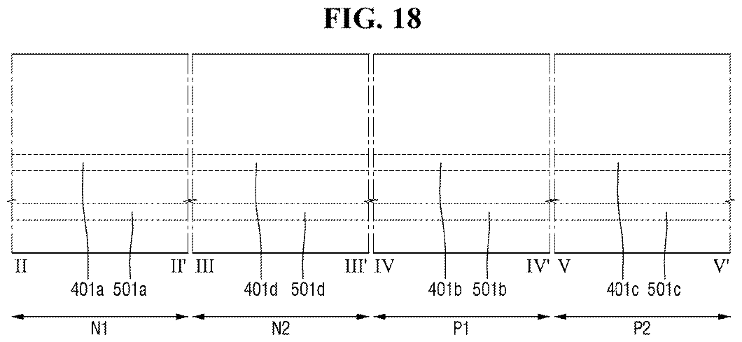

FIGS. 18 to 20 are intermediate step cross-sectional views for explaining a method of fabricating a semiconductor device according to an exemplary embodiment of the present inventive concept.

Referring to FIG. 18, a fifth impurity region 401a, a seventh impurity region 401b, a ninth impurity region 401c, an eleventh impurity region 501a, a twelfth impurity region 501b, a thirteenth impurity region 501c, a fifteenth impurity region 401d, and a sixteenth impurity region 501d are formed in the substrate 100.

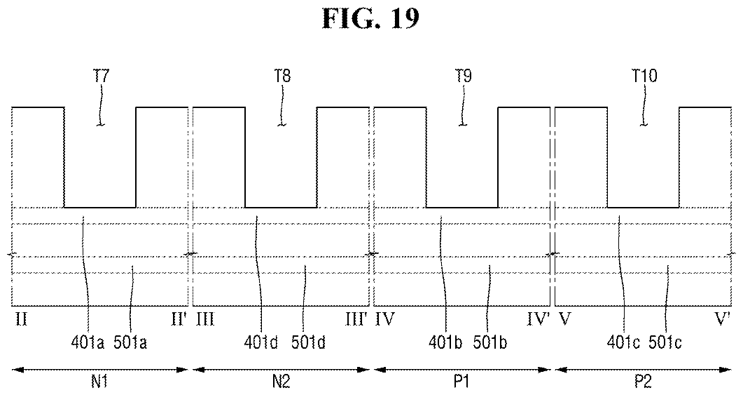

Referring to FIG. 19, a seventh trench T7, an eighth trench T8, a ninth trench T9, and a tenth trench T10 are formed, respectively. For example, a seventh trench T7 may be formed by recessing at least a part of the first NMOS region N1 of the substrate 100. Further, for example, an eighth trench T8 may be formed by recessing at least a part of the second NMOS region N2 of the substrate 100. In addition, for example, a ninth trench T9 may be formed by recessing at least a part of the first PMOS region P1 of the substrate 100. Further, for example, a tenth trench T10 may be formed by recessing at least a part of the second PMOS region P2 of the substrate 100.

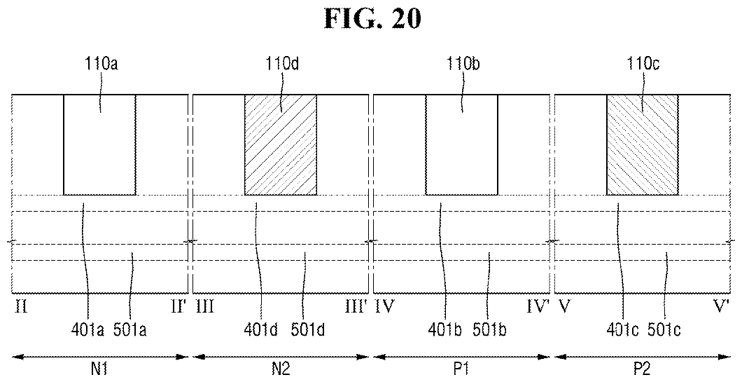

Referring to FIGS. 19 and 20, the first channel layer 110a, the fourth channel layer 110d, the second channel layer 110b, and the third channel layer 110c may be formed in the seventh trench T7, the eighth trench T8, the ninth trench T9 and the tenth trench T10, respectively. According to an exemplary embodiment of the present inventive concept, the first channel layer 110a through the fourth channel layer 110d may be formed, using an epitaxial growth process, a chemical vapor deposition (CVD) process, a physical vapor deposition (PVD) process or the like, but the present inventive concept is not limited thereto. Those having ordinary skill in the technical field of the present inventive concept may form the first channel layer 110a through the fourth channel layer 110d in various ways. As described above, the first channel layer 110a and the second channel layer 110b may include a first material (e.g., silicon (Si)), the third channel layer 110c may include a second material (e.g., silicon germanium (SiGe)), and the fourth channel layer 110d may include a third material (e.g., silicon carbide (SiC)).

Hereinafter, a procedure necessary for fabricating a semiconductor device may be executed according to an exemplary embodiment of the present inventive concept by a method similar to the method described with reference to FIGS. 14 to 17.

The method of fabricating the semiconductor device including all of the first transistor TR1, the second transistor TR2, the third transistor TR3 and the fourth transistor TR4 according to an exemplary embodiment of the present inventive concept has been described with reference to FIGS. 11 to 17 and FIGS. 18 to 20, but the present inventive concept is not limited thereto. For example, a person with ordinary skill in the technical field of the present inventive concept may fabricate a semiconductor device including at least some of the first transistor TR1, the second transistor TR2, the third transistor TR3 and the fourth transistor TR4 through the present inventive concept. Further, a person having ordinary skill in the technical field of the present inventive concept may fabricate a semiconductor device including the first transistor TR1, the second transistor TR2, the third transistor TR3 and/or the fourth transistor TR4, by adding, omitting or changing the specific steps as necessary.

In concluding the detailed description, those skilled in the art will appreciate that many variations and modifications may be made to the preferred exemplary embodiments without departing from the spirit and scope of the present inventive concept. Therefore, the disclosed preferred embodiments of the present inventive concept are used in a generic and descriptive sense only and not for purposes of limitation.

What is claimed is:

1. A semiconductor device comprising:
a substrate including first through third regions;
a first transistor of a first conductivity type disposed on the first region of the substrate and including a first channel layer, wherein the first channel layer includes a first material;
a second transistor of a second conductivity type different from the first conductivity type disposed on the second region of the substrate and including a second channel layer, wherein the second channel layer includes the first material; and
a third transistor of the second conductivity type disposed on the third region of the substrate and including a third channel layer, wherein the third channel layer includes a second material different from the first material.

2. The semiconductor device of claim 1, wherein the second transistor further includes a first source/drain arranged on each of both sides of the second channel layer, and
a first buffer layer disposed between the first source/drain and the second channel layer.

3. The semiconductor device of claim 2, the first source/drain comprises germanium (Ge) having a first germanium (Ge) concentration, and
the first buffer layer comprises germanium (Ge) having a second germanium (Ge) concentration lower than the first germanium (Ge) concentration.

4. The semiconductor device of claim 1, wherein the substrate further comprises a fourth region, and
the semiconductor device further comprises a fourth transistor of the first conductivity type which is disposed on the fourth region of the substrate and comprises a fourth channel layer including a third material different from the first and second materials.

5. The semiconductor device of claim 4, wherein the first material comprises silicon (Si), the second material comprises silicon germanium (SiGe), and the third material comprises silicon carbide (SiC).

6. The semiconductor device of claim 1, wherein the substrate comprises a first impurity region in which concentration of a first impurity is lower than a first concentration, and a second impurity region in which concentration of the first impurity is equal to or greater than the first concentration.

7. The semiconductor device of claim 6, wherein the substrate further comprises a third impurity region which is disposed to be spaced apart from the second impurity region and in which concentration of the first impurity is equal to or greater than the first concentration.

8. The semiconductor device of claim 1, wherein the first channel layer comprises a fourth impurity region in which concentration of a first impurity is lower than a second concentration, and a fifth impurity region in which concentration of the first impurity is equal to or greater than the second concentration, and
the second channel layer comprises a sixth impurity region in which concentration of a second impurity is lower than a third concentration, and a seventh impurity region in which concentration of the second impurity is equal to or greater than the third concentration.

9. The semiconductor device of claim 1, wherein the first to third transistors are fin-type transistors.

10. A semiconductor device comprising:
a first source of a first conductivity type;
a first drain of the first conductivity type spaced apart from the first source;
a first channel layer disposed between the first source and the first drain and including a first material;
a first gate structure on the first channel layer;
a second source of a second conductivity type different from the first conductivity type;
a second drain of the second conductivity type spaced apart from the second source;
a second channel layer disposed between the second source and the second drain and including a second material different from the first material;
a second gate structure on the second channel layer;
a third source of the second conductivity type;
a third drain of the second conductivity type spaced apart from the third source;
a third channel layer disposed between the third source and the third drain and including a third material different from the first and second materials; and
a third gate structure on the third channel layer.

11. The semiconductor device of claim 10, further comprising:
a first buffer layer of the second conductivity type disposed between the second source and the second channel layer; and
a second buffer layer of the second conductivity type disposed between the second drain and the second channel layer.

12. The semiconductor device of claim 11, wherein the second source contains germanium (Ge) having a first germanium (Ge) concentration, the first buffer layer contains germanium (Ge) having a second germanium (Ge) concentration lower than the first germanium (Ge) concentration, the second drain contains germanium (Ge) having a third germanium (Ge) concentration, and the second buffer layer contains germanium (Ge) having a fourth germanium (Ge) concentration lower than the third germanium (Ge) concentration.

13. The semiconductor device of claim 10, further comprising:
a fourth source of the first conductivity type;
a fourth drain of the first conductivity type spaced apart from the fourth source;
a fourth channel layer disposed between the fourth source and the fourth drain and including the second material; and
a fourth gate structure disposed on the fourth channel layer.

14. The semiconductor device of claim 10, wherein the first material comprises silicon carbide (SiC), the second material comprises silicon (Si), and the third material comprises silicon germanium (SiGe).

15. The semiconductor device of claim 10, further comprising:
a first impurity region disposed below the first source and the first drain to prevent punch-through between the first source and the first drain;
a second impurity region disposed below the second source and the second drain to prevent punch-through between the second source and the second drain; and
a third impurity region disposed below the third source and the third drain to prevent punch-through between the third source and the third drain.

16. The semiconductor device of claim 15, further comprising:
a fourth impurity region disposed below the first impurity region to be spaced apart from the first impurity region;
a fifth impurity region disposed below the second impurity region to be spaced apart from the second impurity region; and
a sixth impurity region disposed below the third impurity region to be spaced apart from the third impurity region.

17. The semiconductor device of claim 10, wherein the first channel layer comprises a seventh impurity region in which concentration of a first impurity is lower than a first concentration, and an eighth impurity region in which concentration of the first impurity is equal to or greater than the first concentration, and
the second channel layer comprises a ninth impurity region in which concentration of a second impurity is lower than a second concentration, and a tenth impurity region in which concentration of the second impurity is equal to or greater than the second concentration.

18. The semiconductor device of claim 10, wherein the first gate structure comprises:
a first gate insulating film disposed on the first channel layer;
a first gate electrode formed on the first gate insulating film; and
a first gate spacer disposed on one side of the first gate insulating film and the first gate electrode,
wherein the first gate insulating film extends along an upper surface of the first channel layer and a side wall of the first gate spacer.

19. A semiconductor device comprising:
a substrate including first and second regions;
a first transistor of a first conductivity type disposed on the first region of the substrate and including a first channel layer including a first material; and
a second transistor of the first conductivity type disposed on the second region of the substrate and including a second channel layer including a second material different from the first material,
wherein the first transistor includes:
a first source/drain disposed on each of both sides of the first channel layer and including a third material having a first concentration; and
a first buffer layer disposed between the first channel layer and the first source/drain and including the third material having a second concentration smaller than the first concentration.

20. The semiconductor device of claim 19, wherein the first material comprises silicon (Si), the second material comprises silicon germanium (SiGe), and the third material comprises germanium (Ge).
